(19) United States
(12) Patent Application Publication
(10) Pub. No.: US 2025/0200242 A1
(43) Pub. Date: Jun. 19, 2025

(54) MODELING AND SEQUENCING WIRING ARRANGEMENTS IN AN INDUSTRIAL AUTOMATION ENVIRONMENT

(71) Applicant: Rockwell Automation Technologies, Inc., Mayfield Heights, OH (US)

(72) Inventors: Benjamin R. Henderson, Twinsburg, OH (US); Gregory W. Keller, Jacksonville, FL (US); Shridhar G. Hegde, Bangalore (IN); Lohith K K, Belur Taluk (IN); Sowndarrajan Vijayaragavan, Bengaluru (IN)

(21) Appl. No.: 18/538,851

(22) Filed: Dec. 13, 2023

(51) Int. Cl. G06F 30/18

(52) U.S. Cl. CPC G06F 30/18

(57) ABSTRACT

Systems and methods are disclosed for modeling and defining sequences for assessing wiring arrangements in industrial automation equipment. In one implementation, a computing device is configured to determine accessibility information associated with wired connections of industrial automation equipment from an access point for a technician and determine an installation sequence for the wired connections in the industrial automation equipment based on the accessibility information. The computing device is further configured to generate a display, wherein the display comprises the installation sequence and a model of the industrial automation equipment.

### TECHNICAL FIELD

Various embodiments of the present technology relate to industrial automation systems, and particularly to the installation sequencing and digital modeling of components associated with industrial automation equipment.

### BACKGROUND

Industrial automation environments represent a specialized setting within various industries where advanced technologies and systems are employed to streamline and enhance manufacturing and production processes. The environments encompass the integration of machinery, computer systems, sensors, and software to automate tasks that were previously performed manually, thereby increasing efficiency, precision, and productivity. In such environments, robotics, programmable logic controllers (PLCs), human-machine interfaces (HMIs), and other automation tools are commonly utilized to control and monitor manufacturing operations, often in real-time.

The primary objectives of an industrial automation environment are to reduce human intervention in repetitive or hazardous tasks, minimize errors, improve consistency in product quality, and optimize resource utilization. These environments can be found in a wide range of industries, including automotive, pharmaceuticals, food processing, and aerospace, where they play a pivotal role in modernizing production lines, reducing operational costs, and maintaining a competitive edge in the global market. As technologies continue to advance, industrial automation environments are evolving to incorporate concepts such as the Internet of Things (IoT), artificial intelligence (AI), and data analytics to further enhance decision-making, predictive maintenance, and overall operational efficiency.

However, while the equipment in an industrial automation environment can enhance the manufacturing and production processes, difficulties can arise in building the equipment and maintaining the complex hardware (e.g., control systems and electrical systems) in the equipment. These issues are compounded as new equipment requires additional training and understanding of the configurations of the components in the equipment. This can cause increased training time, increased potential failures in the wiring of the components, and a reduction in the productivity of the technicians managing the equipment.

### SUMMARY

The technology disclosed herein provides sequencing for installing wiring arrangements and components using models of industrial automation equipment. In one embodiment, an apparatus comprises one or more computer readable storage media and program instructions stored on the one or more computer readable storage media that direct at least one processor to determine accessibility information associated with wired connections of industrial automation equipment from an access point for a technician. The program instructions further direct the at least one processor to determine an installation sequence for the wired connections in the industrial automation equipment based on the accessibility information. The program instructions also direct the at least one processor to generate a display, wherein the display comprises the installation sequence and a model of the industrial automation equipment.

### BRIEF DESCRIPTION OF THE DRAWINGS

FIG. 1 is a block diagram of an industrial automation environment with a computer capable of providing guided information about electrical components in industrial equipment according to an implementation.

FIG. 2A is a block diagram of an operational scenario of determining an installation sequence for wired connections in industrial equipment based on accessibility information according to an implementation.

FIG. 2B is a flow diagram of an operation demonstrating the identification of an installation sequence for wired connections in industrial equipment based on accessibility information according to an implementation.

FIG. 2C is a block diagram of a user interface capable of providing guided information about electrical components in industrial equipment according to an implementation.

FIG. 3 is a flow diagram demonstrating an operation of a computer to support guided support for electrical components in industrial automation equipment according to an implementation.

FIG. 4 is a block diagram of a user interface demonstrating a promoted wired connection and display options associated with the wired connection according to an implementation.

FIG. 5 is a block diagram of a user interface demonstrating a promoted wired connection and display options associated with the wired connection according to an implementation.

FIG. 6 is a block diagram of an industrial automation environment with devices capable of supporting guided information about electrical components in industrial equipment according to an implementation.

FIG. 7 is a block diagram of a computing system configured to support guided information about electrical components in industrial equipment according to an implementation.

### DETAILED DESCRIPTION

In the following detailed description of certain embodiments, reference is made to the accompanying drawings which form a part hereof, and in which are shown by way of illustration of example embodiments. It is also to be understood that features of the embodiments and examples herein can be combined, exchanged, or removed, other embodiments may be utilized or created, and structural changes may be made without departing from the scope of the present disclosure.

In accordance with various embodiments, the methods and functions described herein may be implemented as one or more software programs running on a computer processor or controller. Dedicated hardware implementations including, but not limited to, application specific integrated circuits, programmable logic arrays, and other hardware devices can likewise be constructed to implement the methods and functions described herein. Methods and functions may be performed by modules or nodes, which may include one or more physical components of a computing device (e.g., logic, circuits, processors, etc.) configured to perform a particular task or job, or may include instructions that, when executed, can cause a processor to perform a particular task or job, or any combination thereof. Further, the methods described herein may be implemented as a computer readable storage medium or memory device including instructions that, when executed, cause a processor to perform the methods.

In an industrial automation environment, industrial equipment comprises a broad spectrum of technologies and machinery employed in industrial settings to streamline operations, enhance efficiency, and elevate productivity. This equipment includes robotics, programmable logic controllers (PLCs), processors, sensors, conveyor systems, specialized software, and the like that all play a pivotal role in automating tasks and processes within manufacturing and industrial environments.

To support the operation of the industrial equipment, technicians are employed that configure, install, and maintain the various equipment in an environment. Here, to improve the effectiveness of the technicians, each technician can use an end user computing device that displays a virtualized model of the equipment and provides options to better view different components within the equipment. In at least one implementation, the computing device generates a user interface that comprises a model portion with the modeled version of the industrial equipment and an options portion that demonstrates different options in association with displaying the model. From the options, a technician selects a wired connection from a list of available wired connections. The wired connections for the model each represent a wire in the equipment that is coupled to endpoints within the equipment. The list of available wired connections can be organized based on a preferred installation sequence, based potential failure points (e.g., a first wired connections likelihood to fail over another wired connection), based on ease of access, or based on some other factor. In some implementations, the list of available wired connections is sequenced based on shipped product aesthetic similarity (e.g., wires ganged together, tie-wrap locations, path locations, etc.), access to connections for a technician, and identified best practices for efficiency in accessing the termination points and paths for the wires.

In some implementations, a computing device determines a sequence for the wired connections based on accessibility information for the wired connections by a technician of the equipment. The accessibility information comprises orientation information for the wired connections, source and target termination points or components for the wired connections, layering associated with the components in the equipment (e.g., a first set of wires overlaid over another set of wires), or some other factor. Once the accessibility information is determined, the computing device determines the sequence from the accessibility information that can be displayed for the technician. Advantageously, by automating the installation or work sequencing for the wired connections, the technician can more efficiently install and configure the industrial equipment. Specifically, by processing the accessibility information to determine the installation sequence of the wired connections, time and resources are preserved. The technician is not required to install and uninstall wired connections that impede the ability to access another connection, the technician is permitted to efficiently install the wired connections, and the technician is able to quickly identify related connections in the industrial automation equipment.

In response to a selection from the sequence of wired connections, the user computing device generates and updates the model of the industrial equipment to promote the selected wired connection over other wired connections and components. The promotion may comprise highlighting, making larger the wired connection relative to other wired connections, changing the color of the wired connection, or some other mechanism of promoting the wired connection. In some implementations, the computing device promotes the source component, the target component, and the route of the wired connection within the model. In other implementations, the computing device promotes only the path of the wired connection.

Once the wired connection is promoted, the technician provides a selection of at least one display option to modify the display of the model and/or the wired connection in the model. The display options available comprise options to hide one or more components or layers of components of the industrial equipment, options to display the wired connection source, target, and wire path, options to increase or decrease the opacity of the other components in the model, options to rotate or zoom in association with the model, or some other option. Once an option is selected, the computing device reflects the selection by updating the display of the model. Advantageously, the computing device permits the technician to identify the best view for assessing and determining the location of the wired connection relative to the real-world industrial equipment.

In some implementations, the computing device receives feedback about the wired connection from the end user. The feedback can comprise an indication that the wired connection is successfully installed in the equipment, the wired connection was not installed in the equipment, or some other feedback. The feedback is stored in association with the wired connection using the computing device, permitting notes on the connection to be viewed later. In some examples, the computing device further monitors timing associated with the technician work for each of the wired connections, such as the installation time, issue resolution time, or some other information in association with the wired connection.

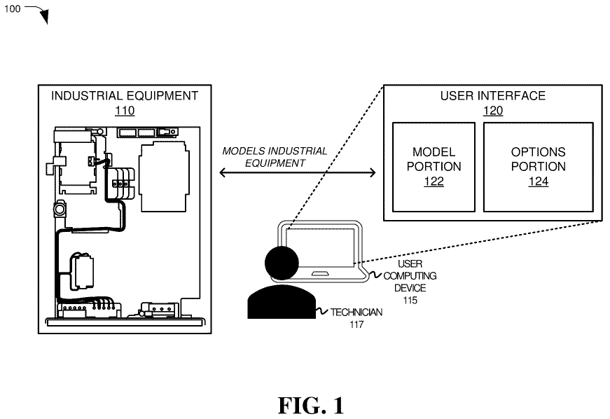

FIG. 1 is a block diagram 100 of an industrial automation environment with a computing device capable of providing guided information about electrical components in industrial equipment according to an implementation. Block diagram 100 includes industrial equipment 110, technician 117, and user computing device 115 that is used to generate user interface 120. User interface 120 comprises model portion 122 and options portion 124. User computing device 115 can be representative of a laptop computer, desktop computer, tablet, smartphone, or some other end user computing device. User computing device 115 includes user interface elements including at least a display and user input components comprising a microphone, mouse, touchscreen, keyboard, or some other user input component.

In the industrial automation environment of block diagram 100, industrial equipment 110 represents a wide range of machines, devices, and systems used in manufacturing and other industrial processes to automate tasks and improve efficiency. These tools can include robotic arms, sensors, PLCs, conveyor systems, processors and storage, and software applications that enable the automation of various production and assembly tasks, reducing human intervention and increasing precision in industrial operations. Industrial automation equipment plays a crucial role in enhancing productivity, reducing labor costs, and ensuring consistent product quality in modern manufacturing environments.

To support industrial equipment 110, an organization employs technicians, such as technician 117, that are responsible for installing, maintaining, and troubleshooting the various automation equipment and systems used in manufacturing processes. Technician 117 ensures that robotic systems, PLCs, sensors, and other components operate smoothly, minimizing downtime and ensuring efficient production in the environment. Here, technician 117 uses an application on user computing device 115 to provide information about industrial equipment 110. The information comprises configuration information associated with different components in industrial equipment 110, wiring guides for routing wired connections in industrial equipment 110, procedural steps for assessing or assembling components and wiring of industrial equipment 110, or some other information associated with industrial equipment 110.

In one implementation, technician 117 initiates a request for a display of information about industrial equipment 110. The request can be generated via a search mechanism on user interface 120, can be generated via scanning a barcode or other identifier associated with industrial equipment 110, can be generated via the input of a code or other identifier associated with industrial equipment 110, or can be generated by some other means. In response to the request, user computing device 115 generates user interface 120 with model portion 122 and options portion 124. Model portion 122 comprises a visual representation of industrial equipment 110 and options portion 124 permits the user to select different visualization or display options associated with industrial equipment 110. The display options comprise a selection of available wired connections in industrial equipment 110 to promote (e.g., promote via color or size in relation to other wires), a selection to rotate or zoom model portion 122, a selection to view the source of a wired connection, a selection to view the target of the wired connection, a selection to view the path between the source and the target for a wired connection, or some other display option.

As an example, technician 117 selects a wired connection from a list of wired connections in options portion 124. In response to the request, user computing device 115 updates model portion 122 to highlight the wired connection in the model of industrial equipment 110. Once highlighted, technician 117 selects various view options to provide clarity or a better visualization of the wired connection. Once viewed, technician 117 performs an action associated with industrial equipment 110, such as adding the wired connection, repairing the wired connection, or testing the wired connection. In some examples, technician 117 reports on the status of the wired connection, such as repaired, completed, failed, and the like that can be viewed by other technicians or users in association with industrial equipment 110 (i.e., distributed to a centralized server or other devices associated with alternative technicians). The status information associated with the wired connection can be displayed at least partially with options portion 124 and stored as part of the data with industrial equipment 110. In some implementations, the status information is maintained locally at user computing device, however, the status information can be maintained remotely in one or more computing systems (e.g., servers) for the environment.

In some examples, technician 117 interacts with user computing device 115 using a keyboard, a touchscreen, a mouse, or some other user input device. In some implementations, technician 117 interacts with user computing device 115 using a headset, microphone, or other input device and user computing device 115 interprets the audio input to perform the desired selections. For example, user interface 120 provides a list of available wired connections associated with industrial equipment 110, wherein the wired connections are organized based on a preferred installation order (assembly order) of the wired connections. Technician 117 provides voice input indicating an identifier of a wired connection (e.g., connection number/identifier in the list) and user computing device 115 promotes the wired connection in model portion 122, wherein the promotion promotes the wired connection over other components (e.g., other wired connections, unrelated motors, circuits, the like from the wired connection). After promoting the wired connection, technician 117 provides user input to select visual options associated with the wired connection. For example, when technician 117 provides input to display related components to the selected wired connection, user computing device can promote the related components in model portion 122. The related components can comprise components reliant on the operation of the wired connection (e.g., components downstream from the wired connection), can comprise components that affect the operation of the wired connection and connected components, or can comprise some other component related to or affected by the wired connection.

Although demonstrated as generating user interface 120 at a local user computing device, in some examples, the computing device generating user interface 120 is remote from the industrial automation environment and the end user device. For example, user computing device 115 can comprise a tablet, a remote client device, or some other computing device capable of remotely connecting to a server generating user interface 120. User computing device 115 executes a remote application designed to allow users to access and control a physical computer or virtual endpoint (i.e., virtual machine) over a network or the internet. The remote application enables a user, such as technician 117, to interact with and utilize the resources and functionalities of a remote system as if they were physically present at the location of that system. Advantageously, the remote device can support additional processing resources that may not be available on user computing device 115 and can generate the required model of the industrial equipment.

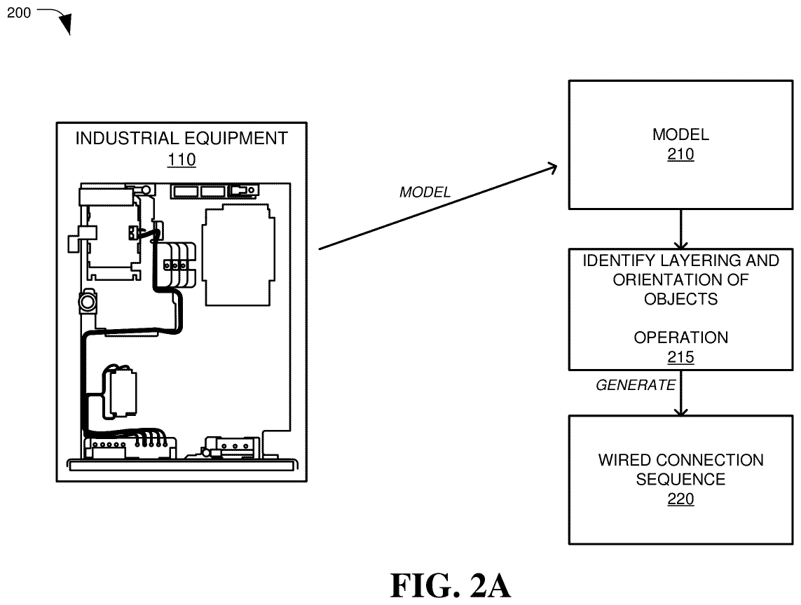

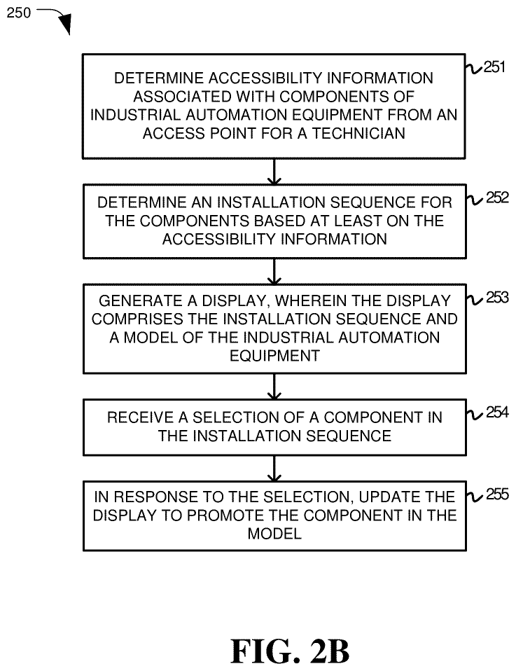

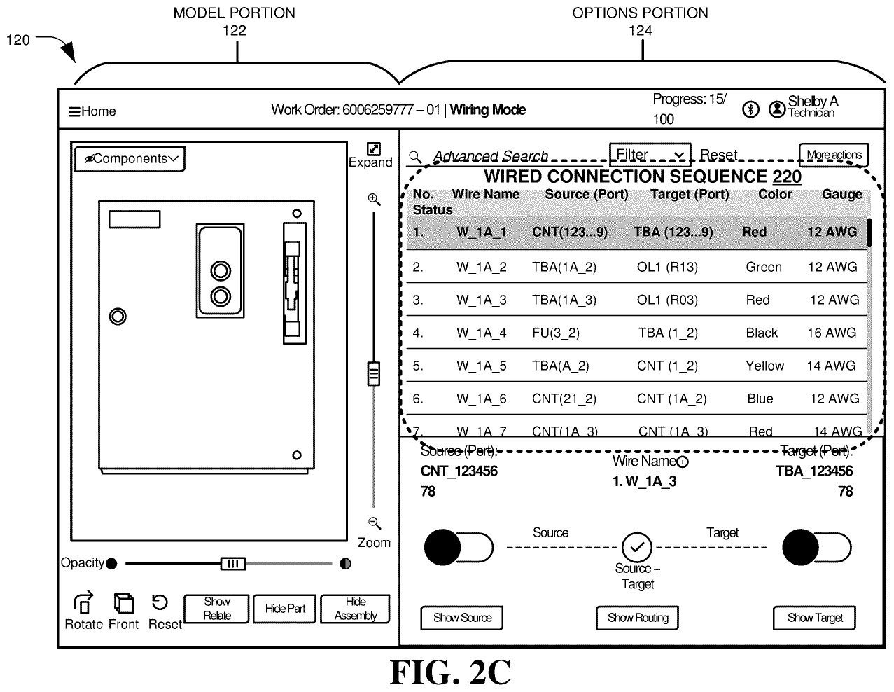

FIG. 2A is a block diagram 200 of an operational scenario of determining an installation sequence for wired connections in industrial equipment based on accessibility information according to an implementation. The block diagram includes industrial equipment 110 from FIG. 1, model 210, operation 215, and wired connection sequence 220. Wired connection sequence 220 is further displayed as part of the user interface in FIG. 2C. The operations in operational scenario 200 can be implemented via an end user device, such user computing device 115 of FIG. 1, or can be provided via one or more remote computing systems, such as servers or desktop computers.

In block diagram 200, a computing device identifies model 210 in association with industrial equipment 110. In some examples, the computing device generates the model based on one or more diagrams or reference sheets associated with the industrial equipment. Specifically, the computing device processes the diagrams to define model 210. In other examples, the computing device receives user input defining the model, scanning the model, or obtaining the model from some other database. Once model 210 is defined, the computing device performs operation 215 that identifies layering and orientation of objects in model 210 relative to an access point for a technician (e.g., front panel, back panel, or some other access point). For example, operation 215 identifies that first wired connections are located near the rear of industrial equipment 110 (i.e., connection points to components are in the rear of the industrial equipment), while second wired connections are located near the front of the industrial equipment. Accordingly, the computing device generates wired connection sequence 220, that indicates the first wired connections should be installed prior to the second wired connections.

In some implementations, the computing device further groups wired connections based on a variety of factors as part of wired connection sequence 220. The grouping factors comprise wired connections that share source and destination endpoints (termination points), wired connections that share at least partially a connection path in industrial equipment 110, or some other factor that can associated a set of wired connection. For example, if a set of five wires shared the same source and destination component (i.e., controller to motor), then the wired connections can be grouped as a set for wired connections sequence 220.

FIG. 2B is a flow diagram of an operation 250 demonstrating the identification of an installation sequence for wired connections in industrial equipment based on accessibility information according to an implementation. The steps of flow diagram 250 are referenced parenthetically in the paragraphs that follow with reference to systems and elements of FIG. 1. In some implementations, the steps of operation 250 are implemented on an end user computing device, such as user computing device 115. In some implementations, the steps of operation 250 are implemented using one or more computing devices, including servers, end user computing devices, and the like.

Operation 250 includes determining (251) accessibility information associated with components of industrial automation equipment from an access point for a technician. The accessibility information comprises orientation of the components in the industrial automation equipment, landing points for wired connections in the industrial automation equipment (source, target, routing points, etc.), layering of the components in the equipment from the access point, or some other accessibility information. For example, industrial equipment 110 comprises a single access panel at the front of the equipment. The computing device providing operation 250 identifies layers of the components from the rear of the equipment to the front of the equipment to determine layering of the components and identify components that are inaccessible after new layers are installed. Thus, a first wired connection at the rear of the equipment may be inaccessible once a second wired connection is installed in the equipment. Accordingly, it may be desirable to install the first wired connection prior to the second wired connection.

After determining the accessibility information, operation 250 further determines (252) an installation sequence for the components based at least on the accessibility information. The components comprise at least wired connections for the industrial equipment, but can further comprise motors, circuits, sensors, or some other electrical component in the industrial equipment. For examples, based on the orientation of components within industrial equipment 110, the computing device determines that a first wired connection interferes with a second wired connection (e.g., the wired connections overlap or are unreachable from the access point once the first wired connection is installed). Accordingly, operation 250 sequences the second wired connection to be installed prior to the first wired connection in the installation sequence. In another example, the computing device determines that a wired connection cannot be installed until a target component is installed. Consequently, the computing device generates an installation sequence that installs other wired connections and components until the target component is available for the wired connection.

Once the installation sequence is determined, operation 250 generates (253) a display, wherein the display comprises the installation sequence and the model of the industrial automation equipment. In some examples, the model of the industrial equipment comprises an empty model that is populated as a technician installs the requisite components, such as wired connections, in the industrial equipment. In other examples, the model comprises at least a portion of the components of the industrial equipment that can be promoted for the technician when selected by the technician. In some implementations, the installation sequence for the wired connections comprises a sequenced list, wherein the list identifies the source and target of the wired connection, the wire gauge type, the wire color, or some other information about the wired connection.

After generating the display that is displayed at the end user device, operation 250 further receives (254) a selection of a component in the installation sequence. The component or wired connection is selected using a mouse, touchscreen, microphone, or some other mechanism. For example, when the display comprises a list of wired connections, the technician uses a touchscreen to select a wired connection from the list. In response to the selection, operation 250 updates (255) the display to promote the selected component in the model. In the example of a selected wired connection, operation 250 promotes the wired connection by adding the wired connection to the model (e.g., when the wired connection was not previously displayed), highlighting the wired connection, increasing the size of the wired connection relative to other wired connections and components, changing the color of the wired connection in the model, or providing some other form of promotion of the wired connection.

After promoting the selected wired connection, the display further comprises display options for the user to change the view associated with the wired connection and the model. The display options can rotate the model, zoom on the model, add or remove the target of the wired connections, add or remove the source of the wired connection, add or remove the path of the wired connection, display related components (e.g., dependent components and coupled components to the wired connection), or provide some other display option in association with the wired connection. Additionally, the display comprises additional wired connections (or other components) for selection by the technician, permitting the technician to select another wired connection in association with the industrial equipment. In response to the selection, the display is updated to present the newly selected wired connection.

In some examples, after promoting a wired connection, the technician provides feedback or status information associated with the wired connection. The status information comprises an indication that the wired connection was successfully installed, an indication of an issue with the wired connection, an indication that materials are required in association with the wired connection, or some other indication. In some implementations, the computing device receives the status information as part of the user interface using user input devices, wherein the user input devices comprise a touchscreen, a mouse, a keyboard, a microphone, a headset, or some other user input device. In some examples, the information about the wired connections further comprises information about the install or repair duration, the duration of an issue associated with the wired connection, or some other information about the install or repair of the wired connection. The information can be stored locally on a computing device or on a server accessible by multiple computing devices and technicians.

In some implementations, the wired connections are grouped based on a variety of different factors for presentation to the technician. For example, the wired connections are grouped in the sequencing based on the accessibility information, wherein the accessibility information comprises shared termination points, shared paths, or other shared commonalities between the wired connections. Thus, wired components that share the same path or shared termination points can be grouped in the sequence that is provided to the technician.

In some examples, the sequencing of the components or wired connections are defined for repairing the industrial automation equipment rather than installing the components in the industrial automation equipment. In one implementation, a technician defines an issue with a wired connection or some other component in the industrial automation equipment. The computing device identifies a sequence of wired connections or components to be tested to resolve the issue. Once identified and provided to the technician, the computing device monitors times associated with resolving the issue, feedback provided by the technician (explicitly through the user interface or using a sensor, such as a multimeter, that provides information about the state of the equipment).

FIG. 2C is a block diagram of a user interface 120 capable of providing guided information about electrical components in industrial equipment according to an implementation. User interface 120 of FIG. 2 is only one example of a potential user interface, and other examples are possible that provide a model of industrial equipment and view options associated with wired connections for the industrial equipment. User interface 120 includes model portion 122, options portion 124, and wired connection sequence 220 from FIG. 2A. Model portion 122 is used to provide a visual representation of the industrial equipment for the technician. Options portion 124 provides a technician with available wired connections in the industrial equipment and view options associated with the selected wired connection.

In one example, a technician can select a wired connection from wired connection sequence 220 in options portion 124, wherein the list of wired connections can be organized based on preferred installation order, based on priority in association with failure, or based on some other factor. In some implementations, the wired connection sequence is determined based on accessibility information associated with the wired connections from an access point for a technician. The accessibility information comprises orientation of the wired connections, source components of the wired connections, target components of the wired connections, layering information for the wired connections, continuity check requirements for the wired connections (e.g., wires installed together to perform a continuity check), or some other accessibility information. Continuity check requirements can group or identify a collection of wires to be installed before a continuity check can be performed for the circuit. Thus, prior to the collection of wires being installed, the user interface indicates that a continuity check cannot be performed. Once the required wired connections are installed, the technician performs the required checks and can update status information associated with the collection of wired connections.

Once a wire is selected, such as the first wire in the list “W_1A_1,” the computing device updates model portion 122 to promote the wired connection in the model. Promoting the wired connection comprises making the selected wire larger than other wires in the model of the industrial equipment, highlighting the wire in the model of the industrial equipment, changing the color of the wire in the model of the industrial equipment, or providing some other promotion associated with the wire. After promoting the wired connection, the technician can select view options associated with the wired connection, including adding or removing layers of the industrial equipment model (i.e., front panel, or layers of components, sub-assemblies, and other wires), adding or removing parts, sub-assemblies, components, or other elements that are unrelated to the wire, zoom changes for the model, rotation changes for the model, selection of relevant portions of the wired connection (source, target, route, etc.), or some other view option.

Once the technician selects a view option from the available view options, the computing device updates user interface 120 to reflect the view option. For example, if the technician selects a view option to remove components in the model or a layer of components in the model (e.g., front panel), the model is updated without the front panel. Additionally, if the technician selects another wired connection in the list of wired connections, the model will be updated to promote the newly selected wired connection in place of the previously selected wired connection.

In some implementations, options portion 124 indicates the different wired connections in the industrial equipment and provides attributes associated with each of the attributes. For each of the connections, user interface 120 provides attributes associated with the wired connection, including the wired name, source information, target information, color, gauge, and the like. The technician uses the information to configure the industrial equipment or diagnose an issue associated with the industrial equipment. For example, using the color of the wire, the technician can determine whether the wire is properly routed by matching the color in the list to the color in the industrial equipment. The wire can also be highlighted in some examples in the model of the equipment.

In some implementations, model portion 122 includes wired connections and components of those installed in the installation process. For example, when the computing device assists a technician in the installation and configuration of the industrial equipment, the computing device will update the model in model portion 122 to include the wired connections completed by the technician. Thus, if the technician has completed five of the wired connections in the list of wired connections, then five completed wired connections will be viewable in the model, while a sixth wired connection is promoted as the next wired connection to be addressed by the technician. Each wired connection indicated as complete by the technician will be reflected in the model, while those that have not been addressed or are not currently being addressed are not visible in the model.

Although demonstrated as selecting a wired connection from a list of available wired connections, in some embodiments, the computing system can support the inverse selection of a wired connection. Specifically, the wired connection can be selected in model portion 122 and the selected wired connection from the model can be highlighted or selected from the list in options portion 124. Advantageously, when a technician encounters an unknown wired connection in the industrial equipment, the technician selects the wired connection in the model of model portion 122 and information about the wired connection is displayed as part of options portion 124. The information about the wired connection comprises, the source, the target, the wire color, the gauge of the wire, or some other information about the wired connection.

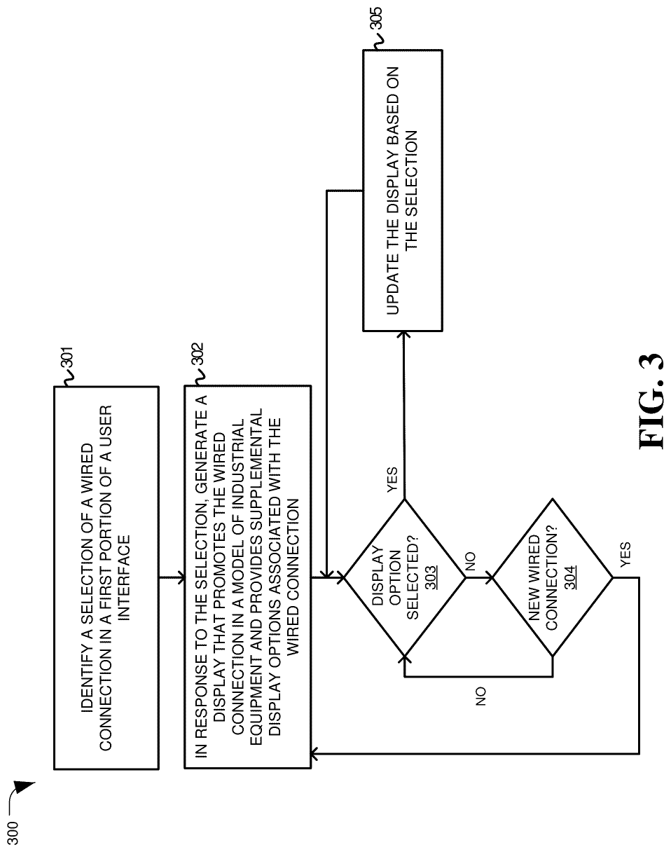

FIG. 3 is a flow diagram demonstrating an operation 300 of a computer to support guided support for electrical components in industrial automation equipment according to an implementation. The steps of operation 300 are referenced parenthetically in the paragraphs that follow. Operation 300 can be performed by a user computing device, such as user computing device 115 of FIG. 1, or can be performed by a computing system remote from the user device, such as a desktop computer, server, and the like.

Operation 300 includes identifying (301) a selection of a wired connection in a first portion of a user interface. In some implementations, the computing device displays a list of available wired connections in association with industrial automation equipment. The wires can be organized based on the order of installation, based on component dependencies, wire path information, based on the layering or accessibility of the wires and components (where a first wire will be inaccessible after installation of a second wire). For example, the computing device provides a list of available wired connections organized based on the preferred order of installation. Once displayed, the technician selects a wired connection from the list of available wired connections.

In response to the selection of the wired connection, operation 300 further generates (302) a display that promotes the wired connection in a model of the industrial equipment and provides supplemental display options associated with the wired connection. In the model of the industrial equipment, the computing device promotes the wired connection using a different color or size associated with the wire relative to other wired connections, highlights the wired connection, or provides some other means of promoting the wired connection. The promoted wired connection can be promoted over any unrelated components to the wired connection, including other wired connections, circuits, motors, sensors, and the like. For example, when the industrial equipment includes 20 wires, the selected wired connection is promoted over the remaining wired connections. In some implementations, the supplemental display options comprise options to rotate or zoom on the industrial equipment model, options to add or remove layers of the industrial equipment model (e.g., front panel, back panel, etc.), options to display the source, the target, and the route of the wire, options to select a different wired connection, options to change the opacity associated with other components than the selected wired connection, options to identify and promote wired connections related to the selected wired connection, or some other display option.

After the display options are provided as part of the display, operation 300 further determines (303) whether one of the display options is selected. If an option is selected, the computing device and operation 300 update (305) the display based on the selection. For example, if a technician selects a view to remove a visible layer of the industrial equipment (i.e., front panel), the computing device will update the model to remove the visible objects associated with the front panel. Alternatively, the technician can select an option to show the source of the wired connection. Accordingly, the computing device will update the display to remove the source associated with the wired connection. Once the model of the industrial equipment is updated, the computing waits for additional technician input.

If an option is not selected by the technician, operation 300 will determine (304) whether the technician selects a new wired connection. In some implementations, the list of available wired connections is displayed after the selection of the first connection. When the technician selects a second wired connection, the computing device generates (302) a display that promotes the second wired connection and no longer promotes the first wired connection. For example, the first wired connection can be highlighted in the model until the second wired connection is selected by the technician. If the technician does not select a new wired connection, the steps of 303-304 are repeated until the technician selects a new display option or selects a different wired connection to be promoted in the visual model.

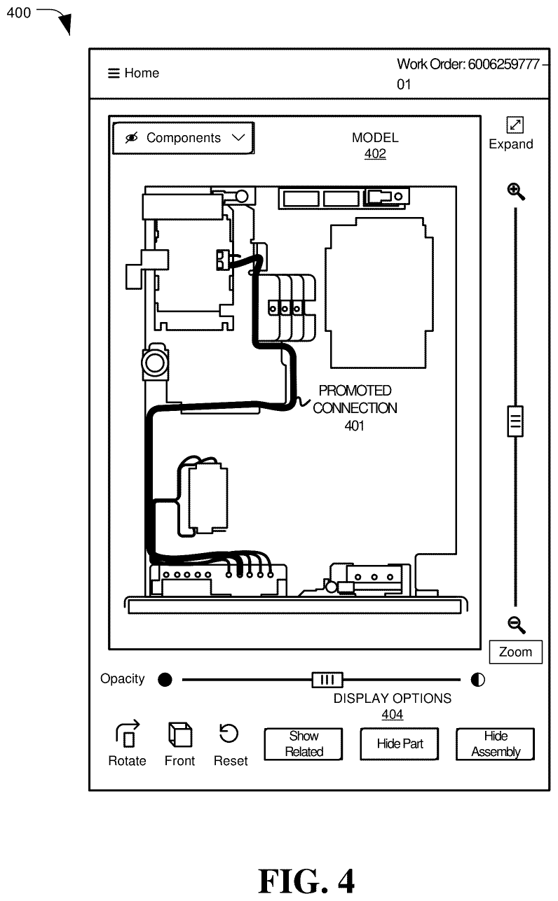

FIG. 4 is a block diagram 400 of a user interface demonstrating a promoted wired connection and display options associated with the wired connection according to an implementation. The user interface includes model 402 that is representative of a model of industrial equipment, promoted wired connection 401, and display options 404. A computing device generates model 402 responsive to a selection by a technician and includes the various wires, components, and other physical elements associated with the industrial equipment. In addition to model 402, the computing device provides display options 404 that permits the technician to manage the zoom associated with the model, show related wired connections to a selected promoted wired connection 401, hide individual parts, control the opacity associated with components other than promoted connection 401, rotate the industrial equipment, select layers associated with the industrial equipment, or provide some other display option in association with promoted connection 401 and the industrial equipment. The computing device promotes promoted connection 401 using different colors, wire sizes than other wires, highlights, or some other mechanism of promoting the wired connection.

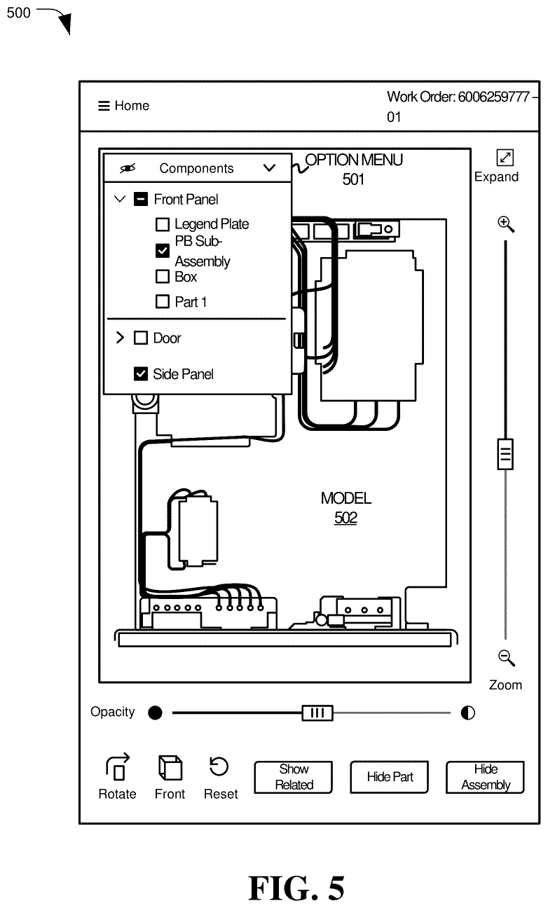

FIG. 5 is a block diagram 500 of a user interface demonstrating a promoted wired connection and display options associated with the wired connection according to an implementation. Block Diagram 500 includes model 502 and option menu 501. Option menu 501 is demonstrative of a drop-down menu that permits a technician to select layers or components associated with industrial equipment. Specifically, the technician can select from various components and layers of the model to make the different components more visible or can add or remove other components from the model. For example, a technician can select to remove a set of one or more components that are not termination points for the wired connection, that are not part of the path of the wired connection, or are unrelated to the wired connection by some other means, wherein the display options comprise a selection to add or remove one or more components unrelated to the wired connection in the industrial automation equipment.

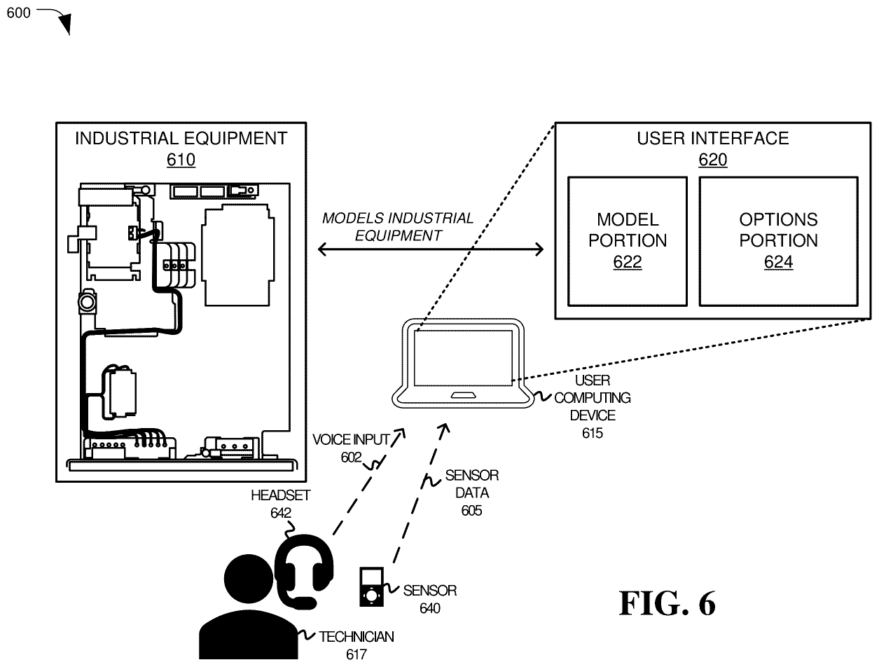

FIG. 6 is a block diagram 600 of an industrial automation environment with devices capable of supporting guided information about electrical components in industrial equipment according to an implementation. Block diagram 600 includes industrial equipment 610, technician 617, and user computing device 615 that is used to generate user interface 620. User interface 620 comprises model portion 622 and options portion 624. User computing device 615 can be representative of a laptop computer, desktop computer, tablet, smartphone, or some other end user computing device. Block diagram 600 further includes sensor 640 and headset 642.

In the industrial automation environment of block diagram 600, industrial equipment 610 represents a wide range of machines, devices, and systems used in manufacturing and other industrial processes to automate tasks and improve efficiency. These tools can include robotic arms, sensors, PLCs (Programmable Logic Controllers), conveyor systems, processors and storage, and software applications that enable the automation of various production and assembly tasks, reducing human intervention and increasing precision in industrial operations.

To support industrial equipment 610, an organization employs technician 617 that assembles and repairs industrial equipment 610 using user computing device 615. User computing device 615 provides user interface 620 with model portion 622 and options portion 624. Model portion 622 provides a visual representation or model of industrial equipment, including at least the wired connections, components, and other electrical equipment within the device. Options portion 624 provides options associated with the display of the model in model portion 622. The options comprise options to zoom the view associated with the model, select, and deselect layers or components associated with the model (e.g., components that are unrelated or not required for the wired connection termination points or path), display different portions of the wired connection (i.e., source, routing, and target), an option to rotate the model, or an option to provide some other display change in association with the model of the industrial equipment.

In the example of the industrial automation environment in FIG. 6, technician 617 further uses headset 642 to interact with and provide voice input 602 to user computing device 615. Headset 642 can be wired to user computing device 615 or can be wirelessly connected to user computing device 615 using Bluetooth, Wi-Fi, or some other wireless standard. In some implementations, technician 642 selects at least one wired connection using voice input 602 from a list of available connections. For example, user computing device 615 displays a list of available wired connections in association with industrial equipment 610, wherein the list can be sequenced as described in FIGS. 2A-2C. The user provides a unique identifier or selection that is recognized by user computing device 615. For example, the user may provide voice input that states “display wired connection number one.” In response to receiving voice input 602, user computing device 615 generates a visual representation or model of industrial equipment 610 with the wired connection promoted within model portion 622. Promoting the wired connection comprises displaying the selected wired connection using a larger path size then one or more other wired connections in the model, highlighting the wired connection, changing the color of the wired connection, or providing some other promotion of the wired connection. In some implementations, user computing device 615 generates options portion 624 that permits technician 617 to provide view preferences in association with the model and the corresponding wire (e.g., view related components and wires to the selected wire). Additionally, options portion 624 provides additional available wired connections for technician 617. In some examples, technician 617 uses headset 643 to select one or more of the display options and/or select another wired connection to be promoted in model portion 622. In some examples, technician 617 provides verbal status information in association with the wired connection, wherein user computing device 615 maintains notes and status information associated with the different wired connections. The status information can be shared with other technicians that support industrial equipment 610. Advantageously, by permitting the user of headset 642 and voice instructions from technician 617, user computing device 615 permits technician 617 to interact with industrial equipment 610 and receive instructions and guided support via user computing device 615.

In addition to or in place of the use of headset 642, the industrial automation environment of FIG. 6 includes sensor 640 that is representative of a multimeter or other device that provides feedback in association with industrial equipment 610. For example, technician 617 selects a wired connection from user interface 620 and information about the wired connection is displayed on user interface 620. The information comprises the promoted wired connection, status information about the wired connection, view options associated with the wired connection, or some other information associated with the wired connection. After selection of the wired connection, technician 617 performs one or more tests on the wired connection using sensor 640. For example, technician 617 performs a circuit continuity check on the wired connection using sensor 640 and sensor data 605 about the check is provided to user computing device 615. In response to receiving sensor data 605, user computing device 615 displays a summary associated with the received sensor data, wherein the summary comprises sensor data 605 itself, a determination whether the sensor data matches the desired data for the wired connection, or some other information about sensor data 605. For example, user computing device 615 indicates that the wired connection is in working condition when sensor data 605 matches or satisfies a desired state for the connection. The desired state for the connection is programmed as part of the software generating user interface 620. Advantageously, technician 617 can check user interface 620 to determine whether the connection is in working condition and make changes as necessary. Sensor data 605 and the state information associated with the wired connection can be stored on computing device 615 and shared with one or more other technicians associated with industrial equipment 615.

In some implementations, based on the feedback from headset 642 or sensor 640, user computing device 615 moves automatically to the next wire in the available wire list. For example, sensor 640 performs a continuity check on a first wire of industrial equipment 610 and indicates that the wire is complete. Sensor 640 provides the indication to user computing device 615 and user computing device 615 updates user interface 620 to move to the next wire in the list of wires. Technician 617 continues the installation or testing operation in association with the next wire without providing feedback directly to the user interface 620.

In some implementations, user computing device 615 connects with one or more servers that generate the user interface. Specifically, user computing device 615 can represent a user device that uses an application to connect to the server over a network and the server generates the user interface. The server can act as a remote desktop or remote application that permits the user to interact with the application as if the application is executed locally on the user device.

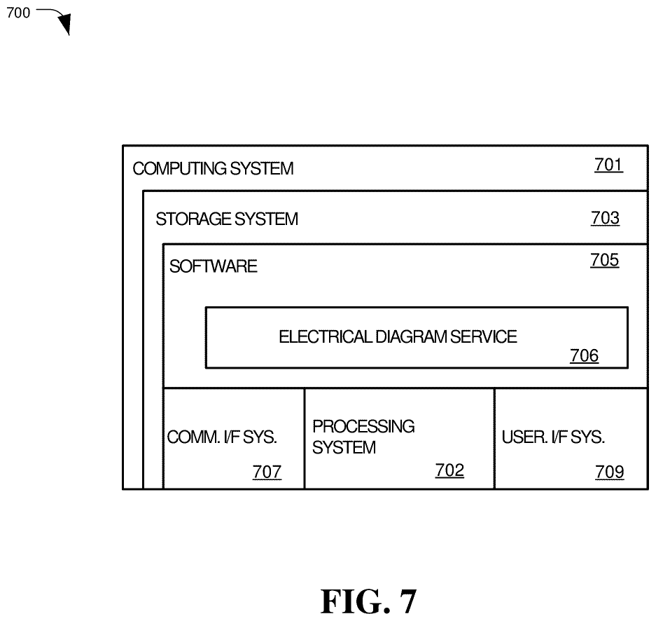

FIG. 7 is a block diagram of an apparatus 700 configured to support guided information about electrical components in industrial equipment according to an implementation. The apparatus 700 includes a computing system 701 that is representative of any system or collection of systems in which the various processes, systems, programs, services, and scenarios disclosed herein may be implemented. For example, computing system 701 may be an example of user computing device 115 of FIG. 1. Examples of computing system 701 include, but are not limited to, server computers, desktop computers, laptop computers, tablets, smartphones, routers, web servers, cloud computing platforms, and data center equipment, as well as any other type of physical or virtual server machine, physical or virtual router, container, communications network equipment, and any variation or combination thereof.

Computing system 701 may be implemented as a single apparatus, system, or device or may be implemented in a distributed manner as multiple apparatuses, systems, or devices. Computing system 701 may include, but is not limited to, processing system 702, storage system 703, software 705, communication interface system 707, and user interface system 709. Processing system 702 may be operatively coupled with storage system 703, communication interface system 707, and user interface system 709.

Processing system 702 may load and execute software 705 from storage system 703. Software 705 may include and implement an electrical diagram service 706, which may be representative of any of the operations for displaying a model of industrial automation equipment, visualizing wired connections (and components), promoting wired connections in the equipment, and managing the view options associated with the equipment as described herein. When executed by processing system 702 to perform electrical diagram service 706, software 705 may direct processing system 702 to operate as described herein for at least the various processes, operational scenarios, and sequences discussed in the foregoing implementations. Computing system 701 may optionally include additional devices, features, or functionality not discussed for purposes of brevity.

In some embodiments, processing system 702 may comprise a micro-processor (i.e., at least one processor) and other circuitry that retrieves and executes software 705 from storage system 703. Processing system 702 may be implemented within a single processing device but may also be distributed across multiple processing devices or sub-systems that cooperate in executing program instructions. Examples of processing system 702 may include general purpose central processing units, graphical processing units, application specific processors, and logic devices, as well as any other type of processing device, combinations, or variations thereof.

Storage system 703 may comprise any memory device or computer readable storage media readable by processing system 702 and capable of storing software 705. Storage system 703 may include volatile and nonvolatile, removable, and non-removable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 703 may also include computer readable communication media over which at least some of software 705 may be communicated internally or externally. Storage system 703 may be implemented as a single storage device but may also be implemented across multiple storage devices or sub-systems co-located or distributed relative to each other. Storage system 703 may comprise additional elements, such as a controller, capable of communicating with processing system 702 or possibly other systems.

Software 705 may be implemented in program instructions that may, when executed by processing system 702, direct processing system 702 to operate as described with respect to the various operational scenarios, sequences, and processes illustrated herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 705 may include additional processes, programs, or components, such as operating system software, virtualization software, or other application software. Software 705 may also comprise firmware or some other form of machine-readable processing instructions executable by processing system 702.

In general, software 705 may, when loaded into processing system 702 and executed, transform a suitable apparatus, system, or device (of which computing system 701 is representative) overall from a general-purpose computing system into a special-purpose computing system customized to implement the systems and processes as described herein. Indeed, encoding software 705 on storage system 703 may transform the physical structure of storage system 703. The specific transformation of the physical structure may depend on various factors in different implementations of this description. Examples of such factors may include, but are not limited to, the technology used to implement the storage media of storage system 703 and whether the computer-storage media are characterized as primary or secondary storage, as well as other factors.

For example, if the computer readable storage media are implemented as semiconductor-based memory, software 705 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 707 may include communication connections and devices that allow for communication with other computing systems (not shown) over communication networks (not shown). Examples of connections and devices that together allow for inter-system communication may include network interface cards, antennas, power amplifiers, radio frequency (RF) circuitry, transceivers, and other communication circuitry. The connections and devices may communicate over communication media to exchange communications with other computing systems or networks of systems, such as metal, glass, air, or any other suitable communication media.

Communication between computing system 701 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of network, or variation thereof.

The illustrations of the embodiments described herein are intended to provide a general understanding of the structure of the various embodiments. The illustrations are not intended to serve as a complete description of all the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Moreover, although specific embodiments have been illustrated and described herein, it should be appreciated that any subsequent arrangement designed to achieve the same or similar purpose may be substituted for the specific embodiments shown.

This disclosure is intended to cover all subsequent adaptations or variations of various embodiments. Combinations of the above embodiments, and other embodiments not specifically described herein, will be apparent to those of skill in the art upon reviewing the description. Steps depicted in the flowcharts may optionally be excluded, added, performed in a different order, or performed with different degrees of concurrency than shown (e.g., steps depicted as sequential may be performed concurrently). Additionally, the illustrations are merely representational and may not be drawn to scale. Certain proportions within the illustrations may be exaggerated, while other proportions may be reduced. Accordingly, the disclosure and the figures are to be regarded as illustrative and not restrictive.

What is claimed is:

1. An apparatus comprising:
one or more computer readable storage media; and
program instructions stored on the one or more computer readable storage media that, when executed by at least one processor, direct the at least one processor to:
determine accessibility information associated with wired connections in industrial automation equipment from an access point for a technician, wherein the accessibility information comprises at least layering information associated with the wired connections in relation to the access point;
determine an installation sequence for the wired connections in the industrial automation equipment based on the accessibility information; and
generate a display, wherein the display comprises the installation sequence and a model of the industrial automation equipment.

2. The apparatus of claim 1, wherein the accessibility information further comprises source components of the wired connections and target components of the wired connections.

3. The apparatus of claim 1, wherein the accessibility information further comprises orientation of the wired connections.

4. The apparatus of claim 1, wherein the program instructions further direct the at least one processor to:
group at least one set of wired connections based on the accessibility information; and
wherein the installation sequence indicates the at least one set of wired connections.

5. The apparatus of claim 1, wherein the program instructions further direct the at least one processor to:
receive a selection of a wired connection in the installation sequence; and
in response to the selection, update the display to promote the wired connection in the model.

6. The apparatus of claim 5, wherein the updated display comprises termination points for the wired connection.

7. The apparatus of claim 5, wherein the updated display comprises display options in association with the wired connection.

8. The apparatus of claim 5, wherein the program instructions further direct the at least one processor to:
identify status information in association with the wired connection, wherein the status information comprises at least timing information associated with installation or resolving an issue associated with the wired connection; and
store the status information with the wired connection.

9. The apparatus of claim 1, wherein the accessibility information further comprises continuity testing information for testing the wired connections.

10. A computing apparatus comprising:
a storage system;
a processing system operatively coupled to the storage system; and
program instructions stored on the storage system that, when executed by the processing system, direct the computing apparatus to:
determine accessibility information associated with wired connections in industrial automation equipment from an access point for a technician, wherein the accessibility information comprises at least layering information associated with the wired connections in relation to the access point;
determine an installation sequence for the wired connections in the industrial automation equipment based on the accessibility information; and
generate a display, wherein the display comprises the installation sequence and a model of the industrial automation equipment.

11. The computing apparatus of claim 10, wherein the accessibility information further comprises source components of the wired connections and target components of the wired connections.

12. The computing apparatus of claim 10, wherein the accessibility information further comprises orientation of the wired connections.

13. The computing apparatus of claim 10, wherein the program instructions further direct the computing apparatus to:
group at least one set of wired connections based on the accessibility information; and
wherein the installation sequence indicates the at least one set of wired connections.

14. The computing apparatus of claim 10, wherein the program instructions further direct the computing apparatus to:
receive a selection of a wired connection in the installation sequence; and
in response to the selection, update the display to promote the wired connection in the model.

15. The computing apparatus of claim 14, wherein the updated display comprises termination points for the wired connection.

16. The computing apparatus of claim 14, wherein the updated display comprises display options in association with the wired connection.

17. The computing apparatus of claim 14, wherein the program instructions further direct the computing apparatus to:
identify status information in association with the wired connection, wherein the status information comprises at least timing information associated with installation or resolving an issue associated with the wired connection; and
store the status information with the wired connection.

18. The computing apparatus of claim 10, wherein the accessibility information comprises continuity testing information for testing the wired connections.

19. A method comprising:
determining accessibility information associated with wired connections in industrial automation equipment from an access point for a technician, wherein the accessibility information comprises at least layering information associated with the wired connections in relation to the access point;
determining an installation sequence for the wired connections in the industrial automation equipment based on the accessibility information; and
generating a display, wherein the display comprises the installation sequence and a model of the industrial automation equipment.

20. The method of claim 19, wherein the accessibility information further comprises the orientation of wired connections, source components of the wired connections, and target components of the wired connections.
